(19) United States
(12) Patent Application Publication
(10) Pub. No.: US 2004/0086015 A1
(43) Pub. Date: May 6, 2004

(54) Semiconductor optical device, semiconductor laser device, semiconductor optical modulation device, and semiconductor optical integrated device

(76) Inventors: Takahiko Kawahara, Yokohama-shi (JP); Michio Murata, Yokohama-shi (JP)

Correspondence Address: SMITH, GAMBRELL & RUSSELL, LLP, 1850 M STREET, N.W., SUITE 800, WASHINGTON, DC, 20036, US

(21) Appl. No.: 10/681,276

(22) Filed: Oct. 9, 2003

(30) Foreign Application Priority Data
Nov. 5, 2002 (JP) P2002-321568

(51) Int. Cl. H01S 5/00

(52) U.S. Cl. 372/45

(57) ABSTRACT

An optical waveguide is provided on an n-type buffer layer. The optical waveguide is formed into a mesa form. A high resistance layer narrows a drive current path through the optical waveguide. Two trenches are formed such that their bottoms are in contact with the high resistance layer. This can effectively narrow the drive current path in the semiconductor laser device part.

### BACKGROUND OF THE INVENTION

1. Field of the Invention

The present invention relates to a semiconductor optical device, a semiconductor laser device, a semiconductor optical modulation device, and a semiconductor optical integrated device.

Related Background Art

Semiconductor optical devices such as semiconductor laser devices which can generate optical signals modulated at a high speed have recently been required for long-distance, large-volume communications. FIG. 1 is a sectional view showing an example of a conventional semiconductor laser device. In this semiconductor laser device 900, an n-type buffer layer 903 is disposed on an n-type semiconductor substrate 902. A first p-type cladding layer 910 is disposed on the n-type buffer layer 903. Between the n-type buffer layer 903 and the first p-type cladding layer 910, an active layer 909 is disposed. Thus, the n-type buffer layer 903, first p-type cladding layer 910, and active layer 909 constitute a semiconductor waveguide part 912. The semiconductor laser device 900 also comprises a high resistance layer 904. The high resistance layer 904 can narrow the drive current path through the active layer 909. A n-type hole blocking layer 905 is disposed on the high resistance layer 904. The n-type hole blocking layer 905 can prevent holes from passing through the high resistance layer 904. A second p-type cladding layer 906 is disposed on the first p-type cladding layer 910 and n-type hole blocking layer 905. A contact layer 907 is disposed on the second p-type cladding layer 906. An anode electrode 911 is formed on the contact layer 907. A cathode electrode 901 is formed on the rear surface of the n-type semiconductor substrate 902.

In the semiconductor laser device 900, the second p-type cladding layer 906 and the n-type hole blocking layer 905 constitute a pn junction. A parasitic capacitance is generated between these layers by the pn junction. The parasitic capacitance cause signal waveforms distorted when driving the semiconductor laser device 900 at a high speed. For lowering the parasitic capacitance, the semiconductor laser device 900 is formed with a pair of trenches 913a and 913b. The trenches 913a and 913b cut through the high resistance layer 904, n-type hole blocking layer 905, second p-type cladding layer 906, and contact layer 907, thereby reaching the n-type buffer layer 903 or the n-type semiconductor substrate 902. The trenches 913a and 913b reduce the pn junction part, thus lowering the parasitic capacitance. Also, since the junction part between the high resistance layer 904 and the second p-type cladding layer 906 becomes smaller, the leakage current passing through the high resistance layer 904 decreases. An insulating film 908 is formed on the surface of the trenches 913a and 913b.

An example of semiconductor laser device having a configuration similar to that mentioned above is disclosed in U.S. Pat. No. 5,717,710.

### SUMMARY OF THE INVENTION

The inventor has been studying how to drive semiconductor optical devices such as the semiconductor laser device 900 more efficiently at a high speed. Thus, the inventor has found the following problem. A current path is formed on the surface of the trenches 913a and 913b, i.e., between the insulating film 908 and semiconductor layers. Then, through this current path, a leak current flows from the second p-type cladding layer 906 to the n-type buffer layer 903, whereby the high resistance layer 904 may fail to narrow the current path through the active layer 909. As a consequence, the conventional semiconductor optical device may fail to make the drive current efficiently flow through the active layer 909.

In the above circumstances, it is an object of the present invention to provide a semiconductor optical device, a semiconductor laser device, a semiconductor optical modulation device, and a semiconductor optical integrated device which can narrow the drive current path effectively.

In accordance with an aspect of the invention, the present invention provides a semiconductor optical device comprising a semiconductor substrate having a main surface; a stripe-shaped optical waveguide, disposed on the main surface of the semiconductor substrate, including an active layer; a current blocking part, disposed on the semiconductor substrate, having the optical waveguide buried therein; a electrically conductive layer disposed on the optical waveguide and current blocking part; a first electrode electrically connected to the semiconductor substrate, and a second electrode electrically connected to the electrically conductive layer; and a trench having a bottom in contact with the current blocking part.

### BRIEF DESCRIPTION OF THE DRAWINGS

FIG. 1 is a sectional view showing an example of conventional semiconductor laser device;

FIG. 2 is a perspective view showing a first embodiment of the semiconductor optical integrated device in accordance with the present invention;

FIG. 3 is a perspective view showing a substrate of the semiconductor optical integrated device shown in FIG. 2;

FIG. 4 is a side sectional view of the semiconductor optical integrated device taken along the line I-I of FIG. 2;

FIG. 5 is a side sectional view of the semiconductor optical integrated device taken along the line II-II of FIG. 2;

FIG. 6 is a side sectional view of the semiconductor optical integrated device taken along the line III-III of FIG. 2;

FIG. 7A is a view showing how a drive current flows in the semiconductor laser device;

FIG. 7B is a view showing how a drive current flows in the conventional semiconductor laser device shown in FIG. 1;

FIGS. 8A to 8C are views showing the method of making a semiconductor optical device in accordance with a second embodiment;

FIGS. 9A and 9B are views showing the method of making a semiconductor optical device in accordance with the second embodiment;

FIG. 10 is a graph comparing a characteristic of the semiconductor laser device with a characteristic of a conventional semiconductor optical device;

FIGS. 11A and 11B are graphs showing the reverse voltage resistance of the semiconductor optical device in accordance with the second embodiment.

### DESCRIPTION OF THE PREFERRED EMBODIMENTS

In the following, the present invention will be explained in detail with reference to the drawings.

First Embodiment

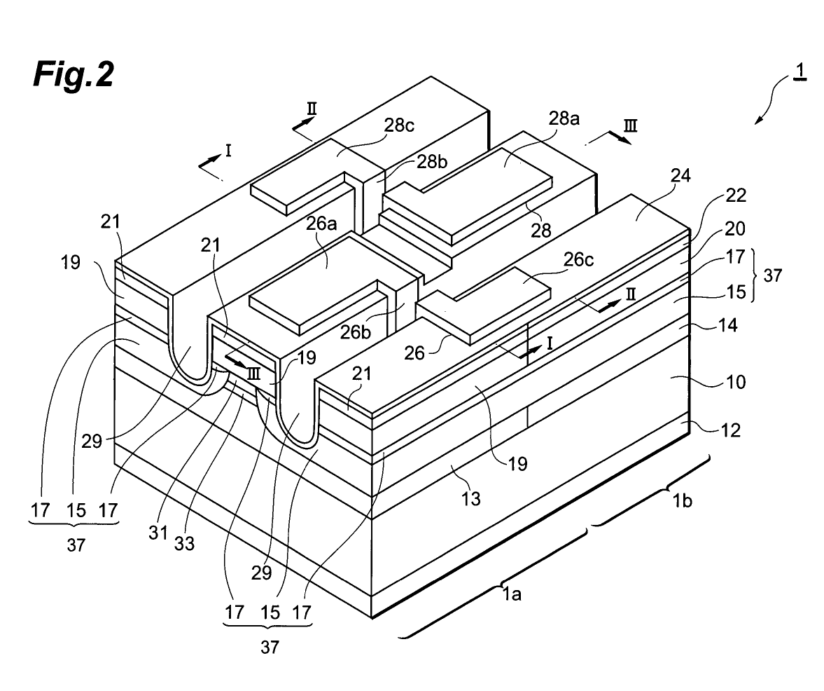

With reference now to FIG. 2, a semiconductor optical integrated device in accordance includes two semiconductor optical devices, i.e., a semiconductor laser device and a semiconductor optical modulation device. These semiconductor optical devices have a flat-surface buried heterostructure. These semiconductor optical devices have an optical waveguide having an heterostructure. The optical waveguide is buried in a semi-insulating semiconductor. These semiconductor optical devices are integrally formed on a substrate. Referring to FIGS. 2 to 6, the semiconductor optical integrated device 1 in accordance with this embodiment will now be explained.

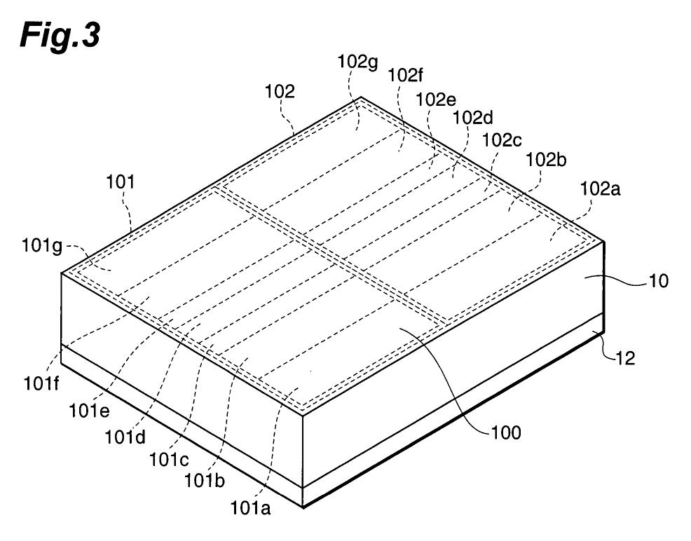

The semiconductor optical integrated device 1 comprises a substrate 10, which is an n-type semiconductor substrate. Referring to FIG. 3, the substrate 10 has a main surface 100. The main surface 100 comprises a laser device region 101 and an optical modulation device region 102. The laser device region 101 and optical modulation device region 102 are arranged in a predetermined axial direction. The laser device region 101 includes a first area 101a, a second area 101b, a third area 101c, a fourth area 101d, a fifth area 101e, a sixth area 101f, and a seventh area 101g. The first area 101a to seventh area 101g extend in the predetermined direction and are successively arranged in a direction intersecting the predetermined direction. The optical modulation device region 102 includes a first area 102a, a second area 102b, a third area 102c, a fourth area 102d, a fifth area 102e, a sixth area 102f, and a seventh area 102g. The first area 102a to seventh area 102g extend in the predetermined direction and are successively arranged in a direction intersecting the predetermined direction.

The semiconductor optical integrated device 1 comprises a semiconductor laser device part 1a disposed on the laser device region 101 and a semiconductor optical modulation device part 1b disposed on the optical modulation device region 102.

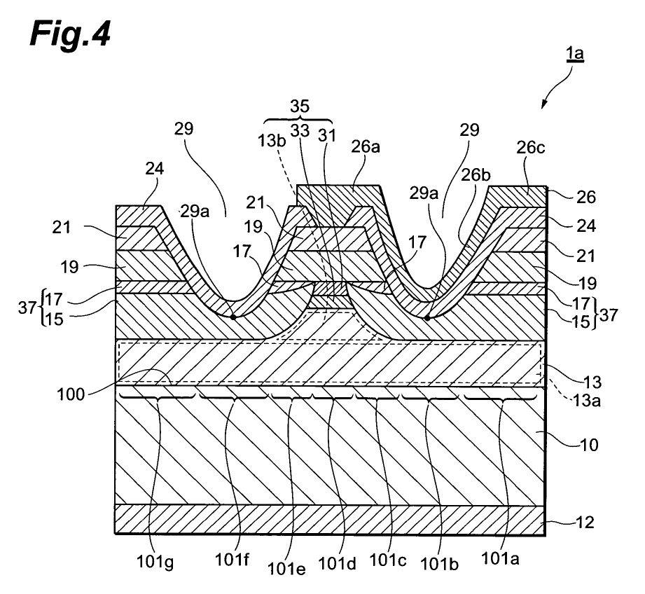

Referring to FIG. 4, the semiconductor laser device part 1a comprises a cathode electrode 12, a first conductivity type semiconductor layer such as an n-type buffer layer 13, a second conductivity type semiconductor layer such as a first p-type cladding layer 31, an active layer 33, a electrically conductive layer such as a second p-type cladding layer 19, a current blocking part 37, a contact layer 21, an insulating film 24, and an anode electrode 26. The current blocking part 37 include a high resistance layer 15 and a hole blocking layer 17.

The n-type buffer layer 13 is made of an n-type InP semiconductor. The n-type buffer layer 13 includes a first part 13a and a second part 13b. The first part 13a is provided on the whole laser device region 101 of main surface 100. The second part 13b is provided on the first part 13a so as to be located on the fourth area 101d of laser device region 101.

The active layer 33 is made of nondoped InGaAsP. The active layer 33 is disposed on the second part 13b of n-type buffer layer 13. The first p-type cladding layer 31 is disposed on the active layer 33. In other words, the active layer 33 is provided between the n-type buffer layer 13 and the first p-type cladding layer 31. The first p-type cladding layer 31 is made of a p-type InP semiconductor. The active layer 33, n-type buffer layer 13, and first p-type cladding layer 31 constitute a double heterostructure, such that carriers are confined into the active layer 33. When carriers move from the n-type buffer layer 13 and first p-type cladding layer 31 into the active layer 33, light is generated in the active layer 33. Materials of the layers are selected such that the active layer 33 has a refractive index higher than that of the n-type buffer layer 13 and first p-type cladding layer 31. This confines the light within the active layer 33. Thereby, the light is guided along the active layer 33 to generate laser light.

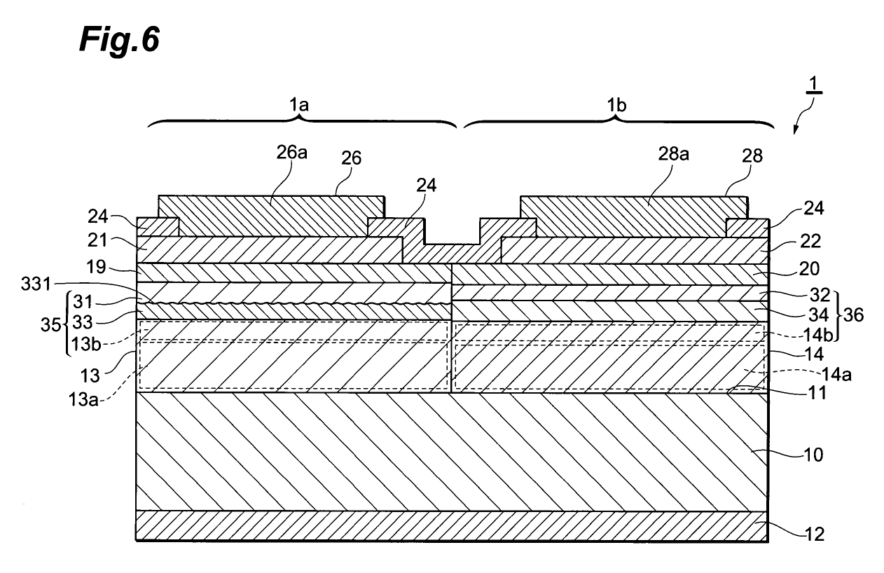

The optical waveguide 35 includes the n-type buffer layer 13, active layer 33, and first p-type cladding layer 31. The optical waveguide 35 is formed into a mesa form. The optical waveguide 35 has a grating structure 331 (shown in FIG. 6). The grating structure 331 is a periodic diffraction grating which optically coupled to the active layer 33. The optical waveguide 35 is shaped into a stripe longitudinally extending in the predetermined direction. As with the second part 13b of the n-type buffer layer 13, the active layer 33 and first p-type cladding layer 31 are disposed on the fourth area 101d of the laser device region 101 on the main surface 100. The active layer 33 and first p-type cladding layer 31 extend in the predetermined direction.

The current blocking part 37 is an element for leading the drive current into the optical waveguide 35. In the semiconductor laser device part 1a, the current blocking part 37 is disposed on the n-type buffer layer 13 so as to be located on the first area 101a to third area 101c and the fifth area 101e to seventh area 101g of the laser device region 101. The current blocking part 37 extends to the semiconductor optical modulation device part 1b, which will be explained later.

The current blocking part 37 includes the high resistance layer 15 and hole blocking layer 17. In the semiconductor laser device part 1a, the high resistance layer 15 is a semi-insulating semiconductor layer. The high resistance layer 15 is made of an InP semiconductor doped with Fe. The high resistance layer 15 has the optical waveguide 35 buried therein. Thereby, the high resistance layer 15 narrows the drive current path to lead the drive current into the optical waveguide 35. The high resistance layer 15 has a semi-insulating property with a resistivity of 10×10⁵ [Ω·m] or higher, for example. The high resistance layer 15 has a resistance value greater than that of the hole blocking layer 17.

The hole blocking layer 17 is disposed on the high resistance layer 15. The hole blocking layer 17 is made of an n-type InP semiconductor which is a semiconductor of a conductivity type opposite from that of the second p-type cladding layer 19. The hole blocking layer 17 is kept from coming into contact with the first p-type cladding layer 31. The hole blocking layer 17 is shaped such that its height from the main surface 100 is substantially the same as the height of the first p-type cladding layer 31 from the main surface 100.

The second p-type cladding layer 19 is provided on the optical waveguide 35 and current blocking part 37. In this embodiment, the second p-type cladding layer 19 is disposed on the first p-type cladding layer 31 and hole blocking layer 17. The second p-type cladding layer 19 is made of a p-type InP semiconductor. The contact layer 21 is made of a p-type InGaAs semiconductor. The contact layer 21 is disposed on the second p-type cladding layer 19.

The semiconductor laser device part 1a comprises two trenches 29. Trenches 29 extend in the predetermined direction along the optical waveguide 35. One of the two trenches 29 is formed on the second area 101b of laser device region 101 on the main surface 100. The other of the two trenches 29 is formed on the sixth area 101f of laser device region 101. Each trench 29 has a bottom 29a in contact with the current blocking part 37. In other words, the trenches 29 are formed so as to reach the current blocking part 37 but not the n-type buffer layer 13, whereas the current blocking part 37 exists between the bottom 29a of each trench 29 and the n-type buffer layer 13. In this embodiment, each trench 29 is formed such that its bottom 29a comes into contact with the high resistance layer 15. Side faces of the trenches 29 are formed by the high resistance layer 15, hole blocking layer 17, second p-type cladding layer 19, and contact layer 21.

The semiconductor laser device part 1a further comprises the insulating film 24, anode electrode 26, and cathode electrode 12. The insulating film 24 is made of SiO₂. The insulating film 24 has an opening on the contact layer 21 so as to be located on the fourth area 101d of laser device region 101. The insulating film 24 is provided on the bottom faces and side faces of the trenches 29.

The cathode electrode 12 is a first electrode electrically connected to the substrate 10. The cathode electrode 12 is disposed on the surface of substrate 10 opposite from the main surface 100. The anode electrode 26 is a second electrode which electrically connected to the second p-type cladding layer 19 by way of the contact layer 21. The anode electrode 26 includes a first part 26a, a second part 26b, and a third part 26c. The first part 26a is disposed on the insulating film 24 so as to be located on the fourth area 101d of laser device region 101. The first part 26a is in contact with the contact layer 21 through the opening of insulating film 24. The third part 26c is disposed on the insulating film 24 so as to be located on the first area 101d of laser device region 101. The second part 26b is disposed on the insulating film 24 so as to connect the first part 26a and third part 26c to each other.

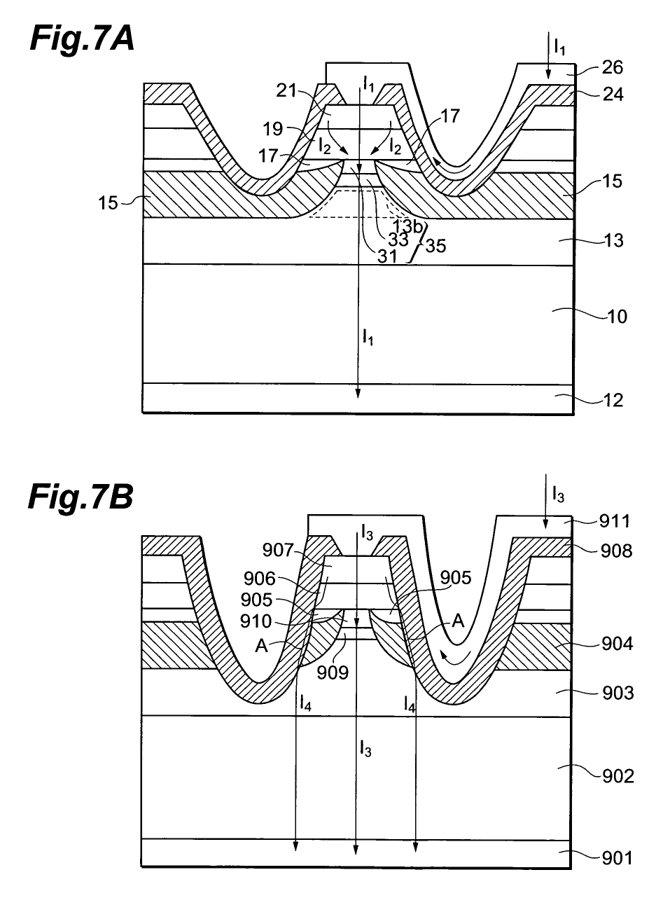

Referring to FIG. 7A, operations of the semiconductor laser device part 1a will be explained.

A driving unit is connected between the cathode electrode 12 and the anode electrode 26. The driving unit applies a positive drive voltage to the anode electrode 26, so as to provide a drive current I₁. By way of the contact layer 21 and second p-type cladding layer 19, the drive current I₁ flows into the optical waveguide 35.

Here, a drive current I₂, which is part of the drive current I₁, spreads within the contact layer 21 and second p-type cladding layer 19. Thereby, the drive current I₂ flows near side faces of the trenches 29 within the second p-type cladding layer 19. The driving current I₂ is narrowed by the high resistance layer 15 of current blocking part 37, so as to be lead into the optical waveguide 35 as shown in FIG. 7A. The hole blocking layer 17 of the current blocking part 37 prevents holes from migrating from the second p-type cladding layer 19 to the n-type buffer layer 13 through the high resistance layer 15. Thus, the current blocking part 37 effectively narrows the path which the drive current flows, thereby leading the drive current into the optical waveguide 35.

As mentioned above, the optical waveguide 35 includes the p-type cladding layer 31, the active layer 33, and the second part 13b of n-type buffer layer 13. As the optical waveguide 35 is supplied with the drive current, carriers flow from each of the first p-type cladding layer 31 and n-type buffer layer 13 into the active layer 33. The carriers are confined into the active layer 33, whereby light is generated within the active layer 33. Since the optical waveguide 35 has the grating structure 331 optically coupled to the active layer 33, laser light which has a specific wavelength is generated within the active layer 33. The active layer 33 emits the laser light in the predetermined direction.

The semiconductor laser device part 1a in accordance with this embodiment has effects as follows. The current blocking part 37 narrows the drive current supplied from the second p-type cladding layer 19 to the optical waveguide 35 and lead it into the optical waveguide 35. On the other hand, the bottoms 29a of trenches 29 are in contact with the current blocking part 37, whereby the current path existing between the current blocking part 37 and the insulating film 24 does not reach the n-type buffer layer 13.

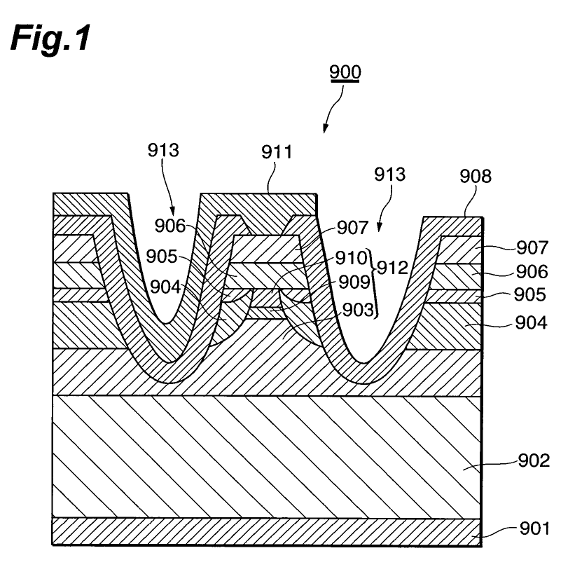

FIG. 7B is a view showing how a drive current flows through the conventional semiconductor laser device shown in FIG. 1. A driving unit is connected between the anode electrode 911 and the cathode electrode 901, whereby the driving unit supplies a drive current I₃ to the anode electrode 911. The drive current I₃ is supplied to the first p-type cladding layer 910 and active layer 909. Here, drive currents I₄, which are part of the drive current I₃, flows from both side faces of the second p-type cladding layer 906 to the n-type buffer layer 903 through current paths A. Then, by way of the substrate 902, the drive currents I₄ flows to the cathode electrode 901. Thus, since the current paths A exist, the drive currents I₄ bypassing the active layer 909, i.e., leak currents, occur in the conventional semiconductor laser device, whereby drive currents cannot be narrowed effectively.

In the semiconductor laser device part 1a in accordance with this embodiment, by contrast, no current paths from side faces of the second p-type cladding layer 19 to the n-type buffer layer 13 are formed separately from the optical waveguide 35. Thereby, leak currents are prevented from flowing between the second p-type cladding layer 19 and the n-type buffer layer 13. Therefore, the drive current applied to the semiconductor laser device part 1a can effectively be narrowed. Since the drive current can efficiently flow into the optical waveguide 35, the semiconductor laser device part 1a can attain a high efficiency. Hence, we can provide a semiconductor laser device which can efficiently convert the drive current into laser light.

In the semiconductor laser device part 1a, no second p-type cladding layer is provided on the second area 101b and fifth area 101e. In other words, the two trenches 29 divide the second p-type cladding layer 19. Here, in thus divided parts of the second p-type cladding layer, the drive current flows through the part held between the two trenches 29. Providing the trenches 29 can lower the parasitic capacitance between the second p-type cladding layer and the n-type buffer layer 13 as compared with the case without the trenches 29. Since the semiconductor laser device part 1a in accordance with this embodiment can prevent leak currents from flowing, the trenches 29 can be provided favorably.

In the semiconductor laser device part 1a, the current blocking part 37 includes the hole blocking layer 17. This can block holes which flow from the second p-type cladding layer 19 to the n-type buffer layer 13 through the high resistance layer 15. Thereby, the current blocking part 37 can narrow the drive current path more effectively.

The semiconductor laser device part 1a preferably comprises the insulating film 24. This can protect the high resistance layer 15, hole blocking layer 17, second p-type cladding layer 19, and contact layer 21.

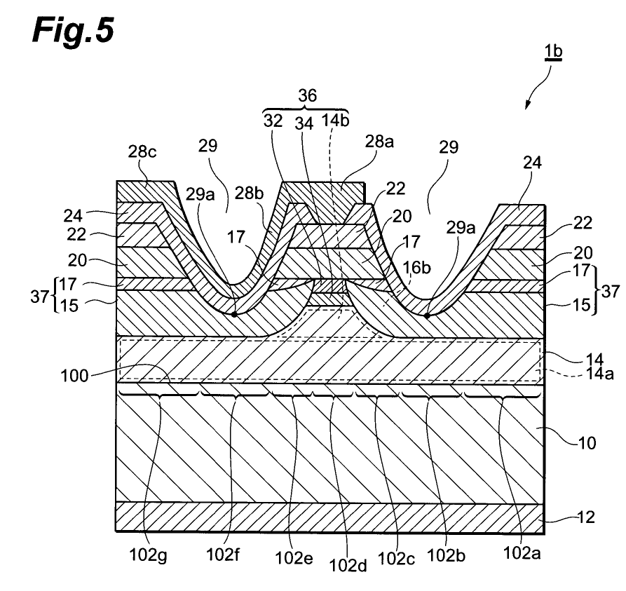

The semiconductor optical modulation device part 1b will now be explained. Referring to FIG. 5, the semiconductor optical modulation device part 1b comprises the cathode electrode 12, a first conductivity type semiconductor layer such as an n-type buffer layer 14, a second conductivity type semiconductor layer such as a first p-type cladding layer 32, an active layer 34, an electrically conductive layer such as a second p-type cladding layer 20, a current blocking part 37, a contact layer 22, the insulating film 24, and an anode electrode 28.

The n-type buffer layer 14 is made of an n-type InP semiconductor. The n-type buffer layer 14 includes a first part 14a and a second part 14b. The first part 14a is disposed on the whole optical modulation device region 102 of main surface 100. The second part 14b is disposed on the first part 14a so as to be located on the fourth area 102d of optical modulation device region 102.

The active layer 34 is disposed on the second part 14b of n-type buffer layer 14. The first p-type cladding layer 32 is disposed on the active layer 34. In other words, the active layer 34 is provided between the n-type buffer layer 14 and the first p-type cladding layer 32. The first p-type cladding layer 32 is made of a p-type InP semiconductor. The active layer 34, n-type buffer layer 14, and first p-type cladding layer 32 constitute a double heterostructure, such that carriers are confined into the active layer 34. Materials of the layers are selected such that the active layer 34 has a refractive index higher than that of the n-type buffer layer 14 and first p-type cladding layer 32. This confines light within the active layer 34. Thereby, the light is guided along the active layer 34. The active layer 34 has an energy band greater than that of the active layer 33 of semiconductor laser device part 1a.

The active layer 34 is optically coupled to the active layer 33 of semiconductor laser device part 1a, so as to receive light emitted from the active layer 33. The optical waveguide 36 includes the second part 14b of n-type buffer layer 14, the active layer 34, and the first p-type cladding layer 32. The optical waveguide 36 is formed into a mesa form. The optical waveguide 36 is shaped into a stripe longitudinally extending in the predetermined direction. As with the second part 14b of n-type buffer 14, the active layer 34 and first p-type cladding layer 32 are disposed on the fourth area 102d of the optical modulation device region 102 on the main surface 100, and extend in the predetermined direction.

The current blocking part 37 extends from the semiconductor laser device part 1a to the semiconductor optical modulation device part 1b. In the semiconductor optical modulation device part 1b, the current blocking part 37 is an element for effectively applying a modulation voltage to the optical waveguide 36. The current blocking part 37 includes a high resistance layer 15 and a hole blocking layer 17. In the semiconductor optical modulation device part 1b, the high resistance layer 15 has the optical waveguide 36 buried therein. The high resistance layer 15 is formed so as to continue from that of the semiconductor laser device part 1a. The high resistance layer 15 is disposed on the n-type buffer layer 14 so as to be located on the first area 102a to third area 102c and fifth area 102e to seventh area 102g of the optical modulation device region 102 on the main surface 100.

The hole blocking layer 17 is made of an n-type semiconductor having a conductivity type opposite from that of the second p-type cladding layer 20. The hole blocking layer 17 is disposed on the high resistance layer 15 so as to continue from the hole blocking layer 17 of semiconductor laser device part 1a. The second p-type cladding layer 20 is disposed on the optical waveguide 36 and current blocking part 37. The second p-type cladding layer 20 has the same configuration as with the second p-type cladding layer 19 of semiconductor laser device part 1a. The contact layer 22 has the same configuration as with the contact layer 21 of semiconductor laser device part 1a. Therefore, no detailed explanations will be provided for the second p-type cladding layer 20 and contact layer 22.

The semiconductor optical modulation part 1b comprises two trenches 29. Trenches 29 extend in the predetermined direction along the optical waveguide 36. One of the two trenches 29 is formed on the second area 102b of optical modulation device part region 102 on the main surface 100. The other of the two trenches 29 is formed on the sixth area 102f of optical modulation device region 102. The two trenches 29 are formed so as to continue from their corresponding trenches 29 in the semiconductor laser device part 1a. Namely, the two trenches 29 connect with those of the semiconductor laser device part 1a, respectively, thereby two trenches are constructed. Each trench 29 has a bottom 29a in contact with the current blocking part 37. In other words, the trenches 29 are formed so as to reach the current blocking part 37 but not the n-type buffer layer 14, whereas the current blocking part 37 exists between the bottom 29a of each trench 29 and the n-type buffer layer 14. In this embodiment, each trench 29 is formed such that its bottom 29a is in contact with the high resistance layer 15. Side faces of the trenches 29 are formed by the high resistance layer 15, hole blocking layer 17, second p-type cladding layer 20, and contact layer 22.

The semiconductor optical modulation device part 1b further comprises the insulating film 24, anode electrode 28, and cathode electrode 12. Among them, the insulating film 24 and cathode electrode 12 are formed so as to continue from that of the semiconductor laser device part 1a.

The anode electrode 28 is a third electrode electrically connected to the second p-type cladding layer 20 by way of the contact layer 22. The anode electrode 28 includes a first part 28a, a second part 28b, and a third part 28c. The first part 28a is disposed on the insulating film 24 so as to be located on the fourth area 102d of optical modulation device region 102. The first part 28a is in contact with the contact layer 22 through an opening of the insulating film 24. The third part 28c is disposed on the insulating film 24 so as to be located on the seventh area 102g of optical modulation device region 102. The second part 28b is disposed on the insulating film 24 so as to connect the first part 28a and the third part 28c to each other.

Operations of the semiconductor optical modulation device part 1b will be explained. A modulation voltage is applied between the anode electrode 28 and the cathode electrode 12 such that the anode electrode 28 side becomes negative. This modulation voltage modulates laser light to an optical signal which includes an output signal. By way of the contact layer 22 and second p-type cladding layer 20, the modulation voltage is applied to the optical waveguide 36. Thus, the modulation voltage is applied between the n-type buffer layer 14 and the first p-type cladding layer 32. Here, the modulation voltage is effectively applied to the optical waveguide 36 by the current blocking part 37.

As the modulation voltage is applied to the optical waveguide 36, laser light is modulated within the active layer 34. Namely, when the modulation voltage is applied to the active layer 34, an electric field causes within the active layer 34. Thereby, absorption wavelength of the active layer 34 shifts because of the quantum confinement Stark effect. As a consequence, when the absolute value of modulation voltage is at a predetermined value or higher, the active layer 34 absorbs the laser light emitted from the active layer 33. When the absolute value of modulation voltage is at a predetermined value or lower, the active layer 34 does not absorb the laser light, but outputs it from the surface opposite from that in contact with the active layer 33. Thus, the active layer 34 modulates the laser light emitted from the active layer 33.

The semiconductor optical modulation device part 1b in accordance with this embodiment has effects as follows. The current blocking part 37 prevents currents from flowing into the n-type buffer layer 14 from the second p-type cladding layer 20 by bypassing the optical waveguide 36. Thereby, the modulation current is effectively applied to the optical waveguide 36. Also, the bottoms 29a of trenches 29 are in contact with the current blocking part 37, whereby the current path existing between the current blocking part 37 and the insulating film 24 does not reach the n-type buffer layer 14. Therefore, leak currents are prevented from flowing between the second p-type cladding layer 20 and the n-type buffer layer 14. As a consequence, the modulation voltage can efficiently be applied to the optical waveguide 36, whereby the semiconductor optical modulation device 1b can attain a high efficiency.

On the other hand, the semiconductor optical modulation part 1b comprising the trenches 29 can reduce the parasitic capacitance between the second p-type cladding layer 20 and the n-type buffer layer 14, and thus can modulate laser light at a high speed.

Second Embodiment

The second embodiment will now be explained as a method of making the semiconductor laser device part 1a in accordance with the first embodiment.

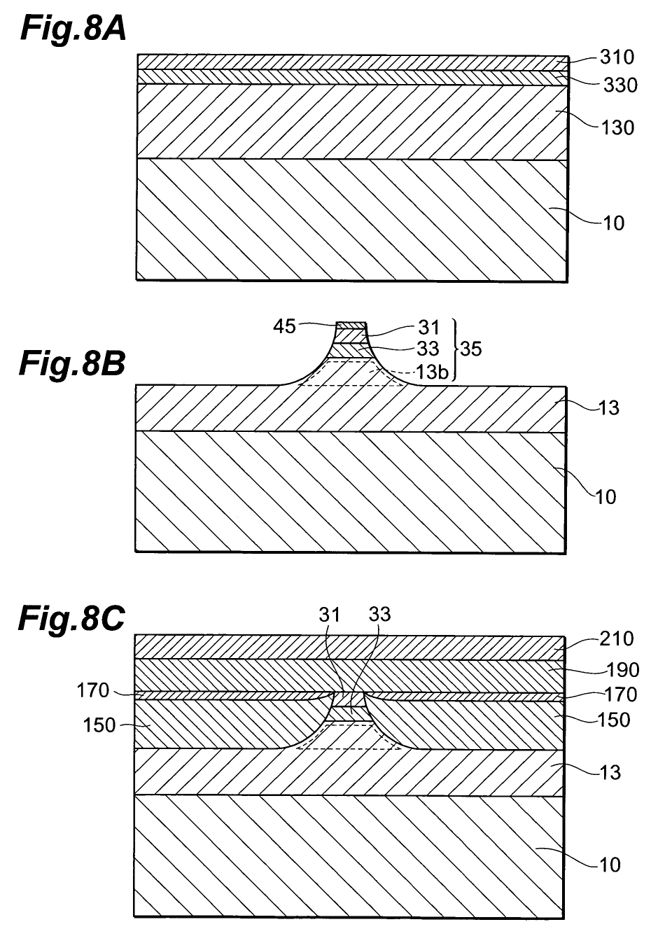

Referring to FIG. 8A, on a substrate 10 made of an n-type InP semiconductor, an n-type InP semiconductor 130 (having a carrier concentration of 1×10¹⁸ cm⁻³) is grown to a thickness of 1 μm by metal organic vapor phase epitaxy. A nondoped InGaAsP semiconductor 330 having an emission wavelength of 1.3 μm is grown thereon to a thickness of 0.5 μm by metal organic vapor phase epitaxy. A p-type InP semiconductor 310 (having a carrier concentration of 5×10¹⁷ cm⁻³) is grown thereon to a thickness of 0.5 μm by metal organic vapor phase epitaxy.

Subsequently, referring to FIG. 8B, a film of SiN is grown to a thickness of 0.1 μm on the surface of the p-type InP semiconductor 310. The film of SiN is formed into a mask 45 by a normal lithography technique such that the mask 45 longitudinally extends in a predetermined direction. Then, the p-type InP semiconductor 310, nondoped InGaAsP semiconductor 330, and n-type InP semiconductor 130 are etched to a depth of 2.0 μm, so as to form a mesa-shaped optical waveguide 35. Here, an n-type buffer layer 13 including a second part 13b, an active layer 33, and a first p-type cladding layer 31 are formed.

Referring to FIG. 8C, an InP semiconductor 150, doped with Fe, having a semi-insulating property is grown on thus etched part by metal organic vapor phase epitaxy. The Fe-doped InP semiconductor 150 preferably has a thickness of at least 1.0 μm, and is grown to a thickness of 1.8 μm in this embodiment. The Fe concentration in the Fe-doped InP semiconductor 150 is preferably at least 5×10¹⁵ cm⁻³ but not greater than 5×10¹⁶ cm⁻³. In this embodiment, the Fe concentration in the Fe-doped InP semiconductor 150 is 1×10¹⁶ cm⁻³.

Then, an n-type InP semiconductor 170 (having a carrier concentration of 1×10¹⁸ cm⁻³) is grown on the Fe-doped InP semiconductor 150 to a thickness of 0.2 μm by metal organic vapor phase epitaxy. As a result, the optical waveguide 35 is buried in the Fe-doped InP semiconductor 150. After removing the mask 45, a p-type InP semiconductor 190 (having a carrier concentration of 1×10¹⁸ cm⁻³) is grown to a thickness of 1.5 μm on the first p-type cladding layer 31 and n-type InP semiconductor 170. A p-type InGaAs semiconductor 210 (having a carrier concentration of 5×10¹⁸ cm⁻³) is grown to a thickness of 0.5 μm on the p-type InP semiconductor 190.

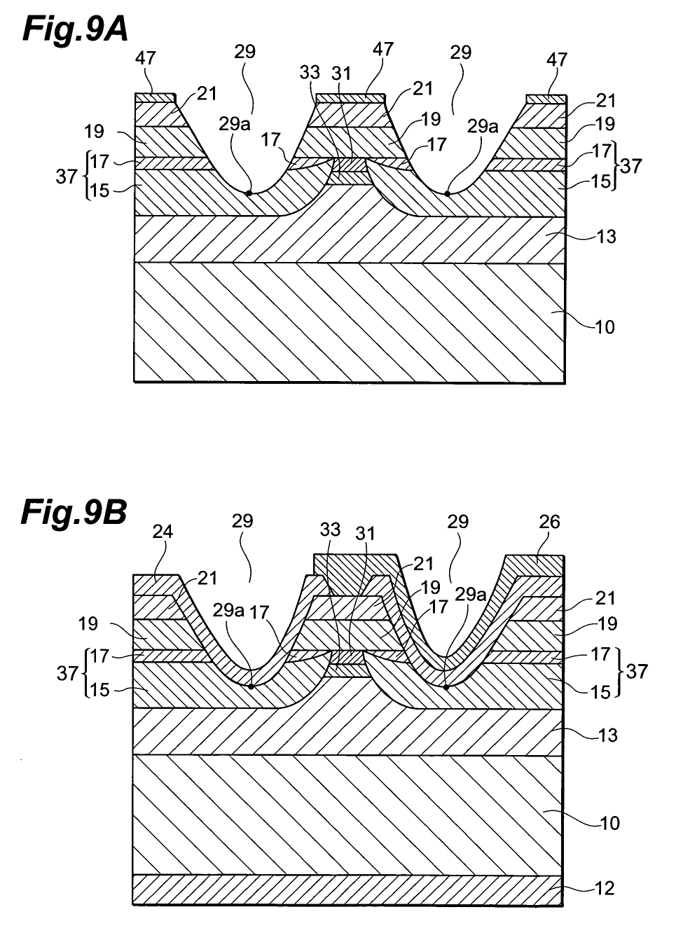

Referring to FIG. 9A, a film of SiN is grown to a thickness of 0.1 μm on the surface of the p-type InGaAs semiconductor 210. The film of SiN is formed into a mask 47 by a normal lithography technique such that the mask 47 longitudinally extends in a predetermined axial direction at the center and both sides of the surface of the p-type InGaAs semiconductor 210. Then, the p-type InGaAs semiconductor 210, p-type InP semiconductor 190, n-type InP semiconductor 170, and Fe-doped InP semiconductor 150 are etched to a depth not to reach the n-type buffer layer 13, so as to form two trenches 29. Thus, a high resistance layer 15 in contact with the bottom 29a of each trench 29 is formed. Also, a hole blocking layer 17, a second p-type cladding layer 19, and a contact layer 21, each divided by the trenches 29, are formed. A current blocking part 37 is provided by forming the high resistance layer 15 and hole blocking layer 17.

Referring to FIG. 9B, after removing the masks 47, an insulating film 24 is formed on the trenches 29. The insulating film 24 is made of an insulating silicon compound such as SiO₂, and is formed with a thickness of 0.3 μm. Then, an anode electrode 26 is formed on the insulating film 24, whereas a cathode electrode 12 is formed on the surface of substrate 10 opposite from the main surface 100. Thus, the semiconductor laser device 1a is completed.

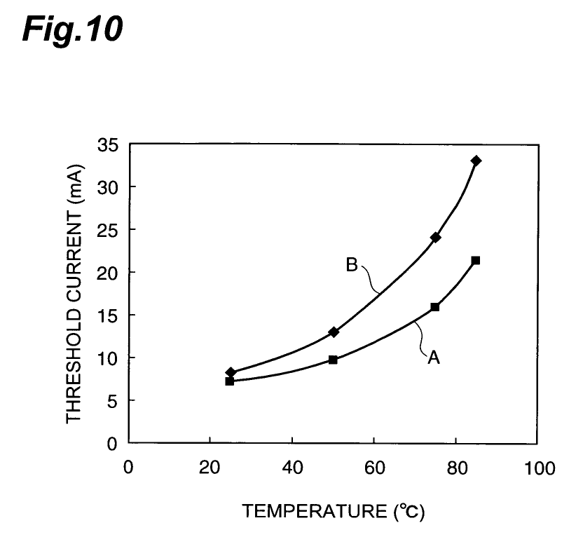

FIG. 10 is a graph comparing a characteristic of the semiconductor laser device 1a in accordance with this embodiment and a characteristic of the conventional semiconductor optical device shown in FIG. 1. The abscissa and ordinate of FIG. 10 indicate temperature and threshold current, respectively. Curves A and B refer to the semiconductor laser device part 1a in accordance with this embodiment and the conventional semiconductor optical device, respectively.

Table 1 in the following shows specific values in the graph of FIG. 10.

TABLE 1

Threshold current

| | | Conventional |
|---|---|---|
| Temp | Embodiment | example |
| 25 | 7.1 | 8.1 |
| 50 | 9.8 | 13.1 |
| 75 | 16 | 24.2 |
| 85 | 21.4 | 33 |

It can be seen from FIG. 10 and Table 1 that the threshold current of the semiconductor laser device part 1a in accordance with this embodiment is lower than that of the conventional semiconductor optical device at all the temperatures. Thus, this embodiment can lower the threshold current of the semiconductor optical device and yield a higher efficiency. This effect is greater at a higher temperature in particular. Namely, the semiconductor optical device in accordance with this embodiment is particularly effective in reducing the leak current at a higher temperature.

Preferably, in the semiconductor optical device, the insulating film is made of an insulating silicon compound such as SiO₂, for example, as in this embodiment. This can lower interface states between the high resistance layer 15 made of an Fe-doped InP semiconductor and the insulating film, and thus is effective as a protective film.

In the semiconductor optical device in accordance with this embodiment, the current blocking part 37 includes the high resistance layer 15 made of an Fe-doped InP semiconductor. The semiconductor optical device preferably includes such a high resistance layer, whereby the current blocking part 37 can favorably narrow the drive current path.

Preferably, in the semiconductor optical device, the high resistance layer 15 has a thickness of at least 1 μm as in this embodiment. As a consequence, the current blocking part 37 can steadily separate the n-type buffer layer 13 and the second p-type cladding layer 19 from each other without breakdown, thereby being able to narrow the drive current path stably.

Preferably, in the semiconductor optical device, the high resistance layer 15 has an Fe concentration of at least 5×10¹⁵ cm⁻³ as in this embodiment. As a consequence, the high resistance layer 15 can steadily separate the n-type buffer layer 13 and the second p-type cladding layer 19 from each other without breakdown, thereby being able to narrow the drive current path stably. Preferably, the high resistance layer 15 has an Fe concentration of 5×10¹⁶ cm⁻³ or less. Thereby, Fe does not diffuse from the high resistance layer 15 into other layers. As a consequence, the reliability of semiconductor optical device can be enhanced.

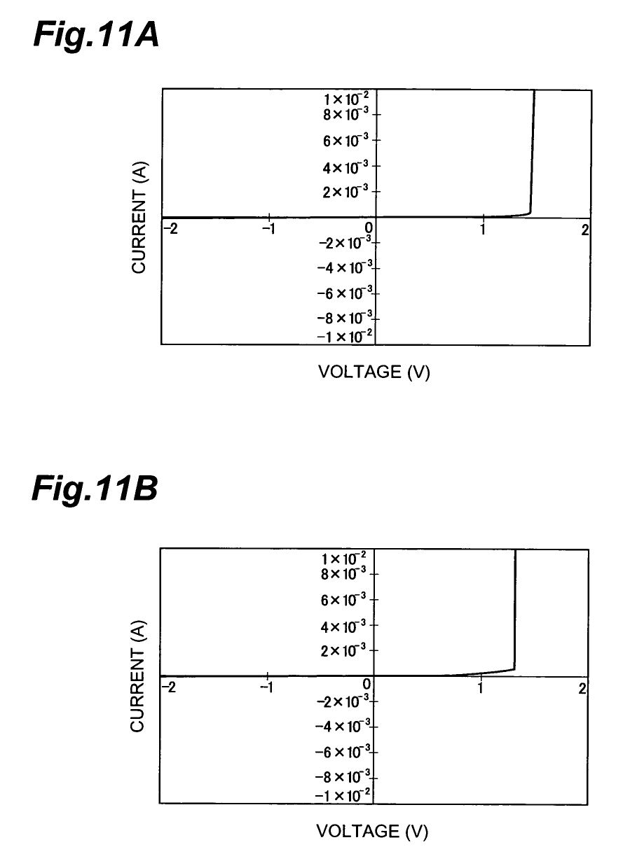

FIGS. 11A and 11B are graphs showing the reverse voltage resistance of the semiconductor optical device in accordance with this embodiment. In FIG. 11A, the Fe concentration of the high resistance layer 15 is set to 5×10¹⁵ cm⁻³, and the high resistance layer 15 has a thickness of 1.5 μm. In FIG. 11B, the Fe concentration of the high resistance layer 15 is set to 1×10¹⁶ cm⁻³, and the high resistance layer 15 has a thickness of 1.0 μm. In each of FIGS. 11A and 11B, the abscissa and ordinate refer to voltage and current, respectively. Temperature is at 85° C. in both cases.

It is seen from FIGS. 11A and 11B that, in case of the high resistance layer 15 has a thickness of 1.5 μm, the reverse voltage resistance, i.e., breakdown voltage, can be made sufficiently high if the Fe concentration is 5×10¹⁵ cm⁻³ or higher. It is also seen that, in case of the Fe concentration is 1×10¹⁶ cm⁻³ or higher, the breakdown voltage can be made sufficiently high if the thickness is 1 μm or greater. It is further seen that leak currents can effectively be reduced even at a high temperature of 85° C.

Without being restricted to the above-mentioned embodiments, the present invention can be modified in various manners. For example, though each of the above-mentioned embodiments relates to a semiconductor optical device of InGaAsP type employing InP as a substrate, effects similar to those of the above-mentioned embodiments can also be obtained in semiconductor optical devices made of other materials.

What is claimed is:

1. A semiconductor optical device comprising:
a semiconductor substrate having a main surface;
a stripe-shaped optical waveguide, disposed on said main surface of said semiconductor substrate, including an active layer;
a current blocking part, disposed on said semiconductor substrate, having said optical waveguide buried therein;
a electrically conductive layer disposed on said optical waveguide and current blocking part;
a first electrode electrically connected to said semiconductor substrate, and a second electrode electrically connected to said electrically conductive layer; and
a trench having a bottom in contact with said current blocking part.

2. A semiconductor optical device according to claim 1, wherein said current blocking part includes a blocking semiconductor layer comprising an InP semiconductor doped with Fe.

3. A semiconductor optical device according to claim 2, wherein said blocking semiconductor layer has a thickness of at least 1 μm.

4. A semiconductor optical device according to claim 2, wherein said current blocking part further includes a hole blocking layer comprising an InP semiconductor of a conductivity type opposite from that of said electrically conductive layer.

5. A semiconductor optical device according to claim 2, wherein said blocking semiconductor layer has an Fe concentration of at least 5×10¹⁵ cm⁻³.

6. A semiconductor optical device according to claim 2, wherein said blocking semiconductor layer has an Fe concentration of 5×10¹⁶ cm⁻³ or less.

7. A semiconductor optical device according to claim 1, further comprising an insulating film disposed on a surface of said trench.

8. A semiconductor optical device according to claim 7, wherein said insulating film comprises an insulating silicon compound.

9. A semiconductor optical device according to claim 1, wherein said optical waveguide comprises a first conductivity type semiconductor layer, a second conductivity type semiconductor layer, and an active layer;
said active layer being provided between said first and second conductivity type semiconductor layers.

10. A semiconductor laser device comprising the semiconductor optical device according to claim 9.

11. A semiconductor optical modulation device comprising the semiconductor optical device according to claim 9.

12. A semiconductor optical integrated device comprising:
a semiconductor substrate having a main surface, said main surface including a laser device region and an optical modulation device region arranged in a predetermined direction;
a stripe-shaped first optical waveguide longitudinally extending in said predetermined direction on said laser device region;
a stripe-shaped second optical waveguide longitudinally extending in said predetermined direction on said optical modulation device region;
a current blocking part, disposed on said semiconductor substrate, having both of said first and second optical waveguides buried therein;
a electrically conductive layer disposed on said current blocking part and first optical waveguide on said laser device region;
a electrically conductive layer disposed on said current blocking part and second optical waveguide on said optical modulation device region;
a first electrode electrically connected to said semiconductor substrate, a second electrode electrically connected to said electrically conductive layer on said laser device region, and a third electrode electrically connected to said electrically conductive layer on said optical modulation device region; and
a trench extending in said predetermined direction along said first and second optical waveguides and having a bottom in contact with said current blocking part;
each of said first and second optical waveguides including a first conductivity type semiconductor layer, a second conductivity type semiconductor layer, and an active layer;
said active layer being provided between said first and second conductivity type semiconductor layers.
